(19) United States
(12) Patent Application Publication
(10) Pub. No.: US 2011/0220176 A1
(43) Pub. Date: Sep. 15, 2011

(54) PORTABLE, DURABLE, INTEGRATED SOLAR POWER GENERATION DEVICE

(75) Inventors: Jason Halpern, Collingswood, NJ (US); Peter Bressler, Philadelphia, PA (US); David R. Schiff, Highland Park, NJ (US); Chris Phelan, Philadelphia, PA (US); Patrick Murphy, Collingswood, NJ (US)

(73) Assignee: POWERFLOWER SOLAR LLC, Haddonfield, NJ (US)

(21) Appl. No.: 13/035,621

(22) Filed: Feb. 25, 2011

Related U.S. Application Data
(63) Continuation-in-part of application No. 12/622,821, filed on Nov. 20, 2009.
(60) Provisional application No. 61/116,561, filed on Nov. 20, 2008.

(51) Int. Cl. H01L 31/052

(52) U.S. Cl. 136/246

(57) ABSTRACT

A solar power generation device comprising a power subunit comprising an array configured to collect solar radiation, and a control subunit removably connected to the power subunit and configured to provide control and motion to the power subunit. The array includes at least one solar module and a pivoting means configured to facilitate movement of the at least one solar module from a closed configuration to an open configuration. The power subunit includes a frame configured to support and move the array. The control subunit includes a tracking system configured to position the array relative to a the sun to maximize collection of solar radiation. When not in use, the solar power generation device may be stacked in a closed configuration with other similar devices on a pallet or other storage device.

### RELATED APPLICATION AND CLAIM OF PRIORITY

This application is a continuation-in-part of and claims the priority benefit of U.S. patent application Ser. No. 12/622,821 filed Nov. 20, 2009, which is hereby incorporated by reference in its entirety and claimed priority to U.S. Provisional Application No. 61/116,561 filed Nov. 20, 2008.

Not Applicable

### BACKGROUND

This document relates to a portable power generation device. More specifically, the present disclosure relates to a portable solar power generation device.

Solar power offers a number of advantages. For example, solar power offers the promise of clean, renewable energy. In addition, solar power may be generated wherever solar radiation is available. Thus, solar power may facilitate a decentralized energy system by enabling electricity to be generated at or near the point of consumption. Moreover, solar power may be generated without the use of hydrocarbons, thereby reducing our dependence on fossil fuels. However, to date, developments in concentrated solar power generation have failed to address certain needs of the end user, and do not take full advantage of solar energy's beneficial characteristics.

In particular, existing solar installations are generally permanent, while many possible uses of solar energy require temporary installations. As an example, in the agricultural sector, a farmer may want to harvest solar power during a certain period of time over which a field would otherwise go unused. The permanence of existing installations makes such a use unfeasible due to the lengthy and costly installation process. In addition, many of the current solar technologies cannot withstand harsh operating environments. The critical functional surfaces on solar generators (e.g., mirrors, lenses, glass coverings, solar panels and/or cells) that are frequently exposed to dust or chemicals, for example, may become damaged or coated by dust or other debris, thus reducing overall effectiveness. Moreover, existing installations are often very complex, typically requiring a large amount time to install by trained experts. In addition, existing solar installations are not easily moved to and from the location of installation. What is needed is a portable or semi-portable solar power generation device, capable of rapid scaled deployment by an end user of the electricity or an independent electricity generator.

### SUMMARY

This disclosure is not limited to the particular systems, devices and methods described, as these may vary. The terminology used in the description is for the purpose of describing the particular versions or embodiments only, and is not intended to limit the scope.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this document is to be construed as an admission that the embodiments described in this document are not entitled to antedate such disclosure by virtue of prior invention. As used in this document, the term “comprising” means “including, but not limited to.”

In one general respect, the embodiments disclose a solar power generation device comprising a power subunit comprising an array configured to collect solar radiation, and a control subunit removably connected to the power subunit and configured to provide control and motion to the power subunit.

In an alternative embodiment, the array may further comprise a module frame, at least one solar module operably connected to the module frame, and a pivoting means operably connected to the at least one solar module and configured to facilitate movement of the at least one solar module from a closed configuration to an open configuration.

In an alternative embodiment, the power subunit may further comprise a frame configured to support the array, a moving frame operably connected to the frame and configured to move the array, at least one fastening feature, at least one locating feature, at least one forklift interface and a human interface.

In an alternative embodiment, the control subunit may comprise a base and a tracking system operably connected to the base and configured to position the array relative to a source of the solar radiation.

In an alternative embodiment, the tracking system may comprise a rotation means configured to rotate the array and an actuator operably attached to the rotation means and configured to actuate movement of the rotation means.

In an alternative embodiment, the base of the control subunit may comprise an energy storage system, an electronic control system, at least one fastening feature, at least one locating feature, at least one forklift feature and a human interface.

In an alternative embodiment, the solar power generation device may be configured to be stacked in a closed configuration with other similar solar power generation devices on a pallet.

### BRIEF DESCRIPTION OF THE DRAWINGS

Aspects, features, benefits and advantages of the present invention will be apparent with regard to the following description and accompanying drawings, of which:

FIG. 1 illustrates an isometric view of an exemplary solar power generation device in an open configuration according to an embodiment;

FIG. 2 illustrates an isometric view of an exemplary solar power generation device in a closed configuration according to an embodiment;

FIG. 3 illustrates a system diagram of an exemplary solar power generation device according to an embodiment;

FIG. 4 illustrates an isometric view of an exemplary control subunit according to an embodiment;

FIG. 5 illustrates a bottom view of an exemplary control subunit according to an embodiment;

FIGS. 6A and 6B illustrate front and back perspective views of an exemplary power subunit according to an embodiment;

FIG. 7 illustrates an isometric view of stacked solar power generation devices according to an embodiment;

FIG. 8 illustrates a cross section view of an exemplary power subunit according to an embodiment;

FIG. 9 illustrates a stack of exemplary power subunits according to an embodiment;

FIG. 10 Illustrates an exemplary method for an exemplary solar power generation device to transition from a protected configuration to an open configuration according to an embodiment;

FIGS. 11A and 11B illustrate an exemplary alternative linkage for actuation of an angle of an array according to an embodiment;

FIGS. 12A and 12B illustrates an alternative embodiment including a tensioning means according to an embodiment;

FIG. 13 illustrates an alternative embodiment including a wind mitigation apparatus according to an embodiment;

FIG. 14 illustrates a first network system diagram according to an embodiment;

FIG. 15 illustrates a second network system diagram according to an embodiment;

FIG. 16 illustrates a third network system diagram according to an embodiment;

FIG. 17 illustrates a fourth network system diagram according to an embodiment;

FIG. 18 illustrates an alternative frame according to an embodiment;

FIGS. 19A and 19B further illustrate an alternative frame according to an embodiment;

FIG. 20 further illustrates alternative frames according to an embodiment; and

FIG. 21 further illustrates alternative frames according to an embodiment.

### DETAILED DESCRIPTION

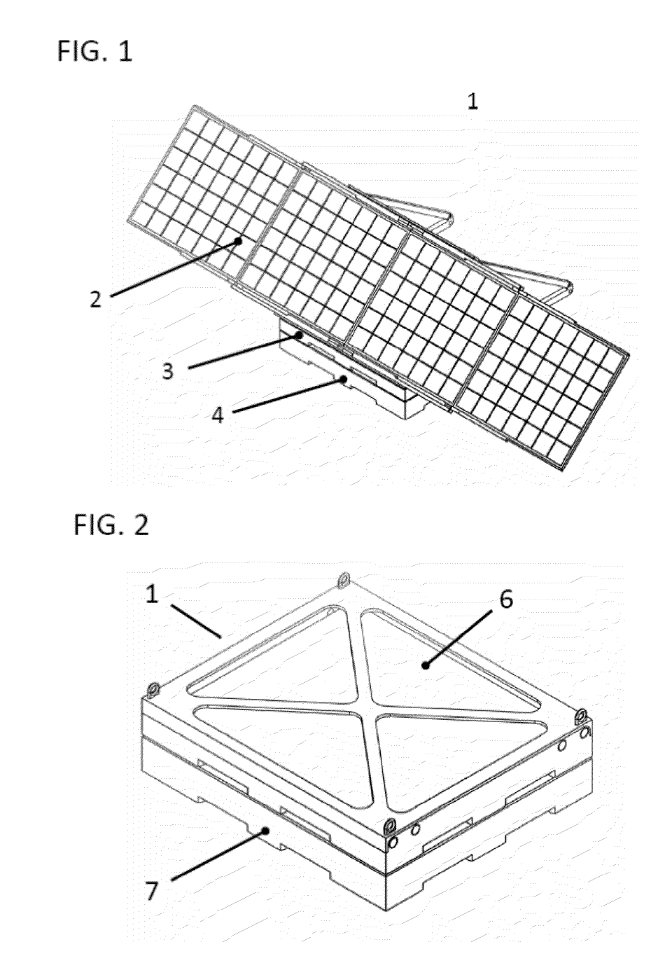

FIG. 1 illustrates an overall structure of an exemplary alternative embodiment of a solar power generation device 1 in an open configuration. As shown in FIG. 1, the solar power generation device 1 may include an array 2, a frame 3, a tracking system 4, and a base 5.

FIG. 2 illustrates the overall structure of the solar power generation device 1 in a packed configuration. As shown in FIG. 2, the solar power generation device 1 may further include a power subunit 6 and a control subunit 7.

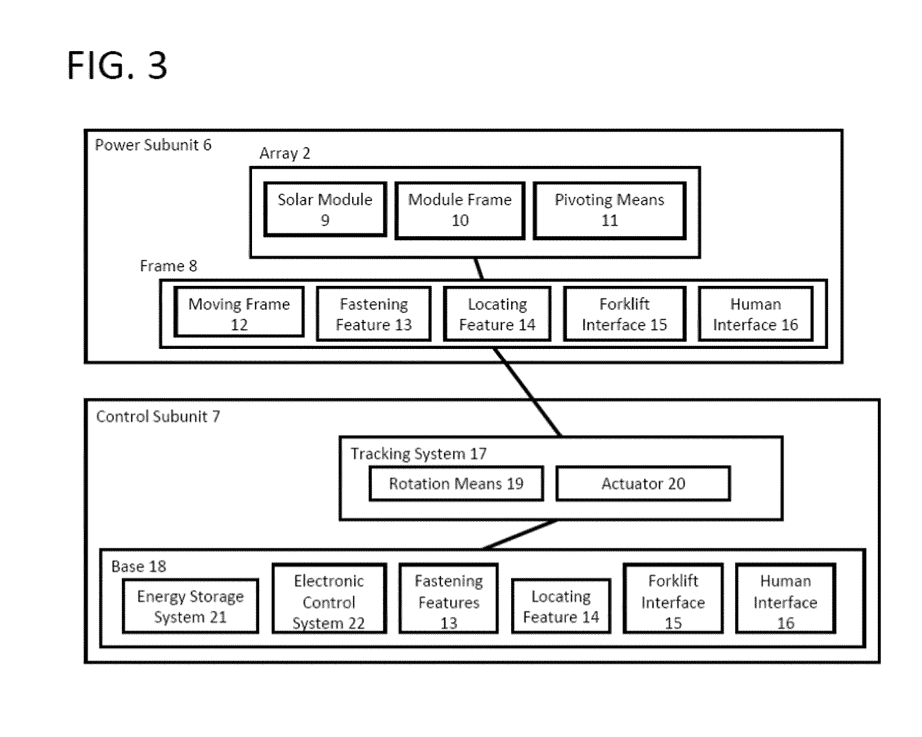

FIG. 3 illustrates an exemplary system diagram of the solar power generation device 1. The power subunit 6 may include an array 2, and a frame 8. The array 2 may include or contain one or more solar modules 9, one or more module frames 10, and one or more pivoting means 11. The frame 8 may include one or more moving frames 12, one or more fastening features 13, one or more locating features 14, a forklift interface 15, and a human interface 16. The control subunit 7 may include or contain a tracking system 17 and a base 18. The tracking system 17 may include a rotation means 19 and an actuator 20. The base 18 may include an energy storage system 21, an electronic control system 22, one or more fastening features 13, one or more locating features 14, a forklift interface 15, and a human interface 16. It should be noted that this diagram represents one exemplary embodiment of the invention and that alternative embodiments may include a combination of any of the included components. In other alternative embodiments of the invention, the distribution of parts among the subunits may vary. For example, in an alternative embodiment the tracking system 17 may be a part of the power subunit 6. In a preferred embodiment of the invention, the power subunit 6 and the control subunit 7 may function together or independently. Alternative embodiments of the invention may not by divided into subunits.

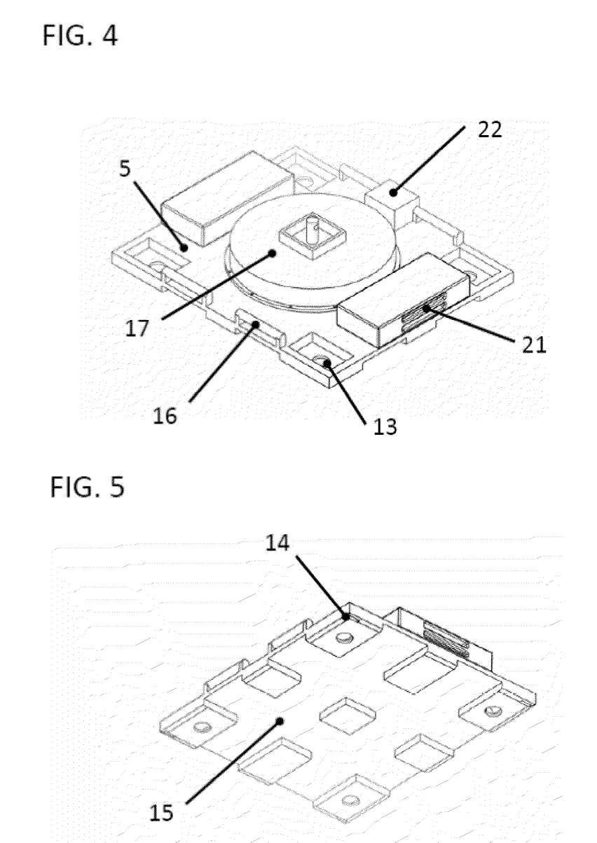

FIG. 4 illustrates an isometric view of an exemplary embodiment of the control subunit 7. As discussed above, the control subunit 7 may contain a base 5. In a preferred embodiment, the base 5 may be constructed from a structural foam or other similar material. In alternative embodiments, the base 5 may be constructed from any combination of materials, for example metals, plastics, and/or composites.

As described above, the base 5 may contain a tracking system 17. The tracking system 17 may include a rotation means 19 that is attached to the base 5 and the frame 8. The rotation meals 19 may and allow the base 5 and the frame 8 to move relative to each other and an actuator 20. In a preferred embodiment, the rotation means 19 may include a rotary bearing. In alternative embodiments the rotation means 19 may include wheels and a track or any other components that would facilitate the motion of the frame 8 relative to the base 5.

In an alternative embodiment, the solar power generation device 1 may not include a tracking system 16. In this configuration, the frame 8 may be mounted directly to the base 5. Alternatively, the solar power generation device 1 may not include the base 5 and the tracking system 4.

As described above, the base 5 may include a human interface 16. The human interface 16 may include features that facilitate interfacing the human body with the solar power generation device 1 for the purpose of moving of positioning the device. For example, the human interface 16 may include handles. In addition, the human interface 16 may include features that facilitate the flow of information to and from a user and the solar power generation device 1 such as a digital display or other graphical user interface.

As described above, the base 5 may include an energy storage system 20. The energy storage system 20 may include any components necessary to manage and store electrical energy within the solar power generation device 1.

As described above, the base 5 may further include an electronic control system 21. The electronic control system 21 may contain any components necessary to control the operation and flow of energy within the solar power generation device 1. Additionally, the electronic control system 21 may contain a means to interface with other electrical components, for example male or female electrical connectors.

As described above, the base 5 may further include at least one fastening feature 13. The fastening features 13 may allow the frame to be attached to the ground or other surface or object. The fastening features 13 may be integral to the base 5, or additional components may be added to provide the fastening features 13. In alternative embodiments, the base 5 may not include fastening features 13.

FIG. 5 illustrates a bottom view of an exemplary embodiment of the control subunit 7. As described above, the base 5 may contain a forklift interface 15. In a preferred embodiment, the forklift interface 15 is integral to the base 5. In alternative embodiments, the forklift interface 15 may be formed from additional components and attached to base 5. In further additional embodiments, the forklift interface 15 may be absent or not permanently connected to the base 5. As mentioned above, the base 5 may contain locating features 14. In a preferred embodiment, the locating features 14 may be integral to the base 5. In alternative embodiments, the locating features 14 may be formed from additional components and attached to the base 5. In further additional embodiments, the locating features 14 may be absent or not permanently connected to the base 5.

The forklift interface 15 on the bottom of the control subunit 7 may allow for movement of the unit by pallet moving equipment such as forklifts or pallet trucks. In a preferred embodiment, the forklift interface 15 allows for 4 directions of entry by pallet moving equipment, but in alternative embodiments of the invention the forklift interface 15 may consist of any geometry that allows the unit to be lifted by pallet moving equipment. Alternatively, the forklift interface 15 may not be included.

In an alternative embodiment of the control subunit 7, the energy storage system 21 is located in a space defined between the forklift interface 15. In a preferred embodiment, the control subunit 7 features a human interface 16 to allow it to be carried by one or more people. In the preferred embodiment, the energy storage system 21 may be enclosed in containers that have a human interface 16 that allows the containers to be moved by one or more people separate from the control subunit 7. In an alternative embodiment, the batteries may be integral to another component, for example the base 5.

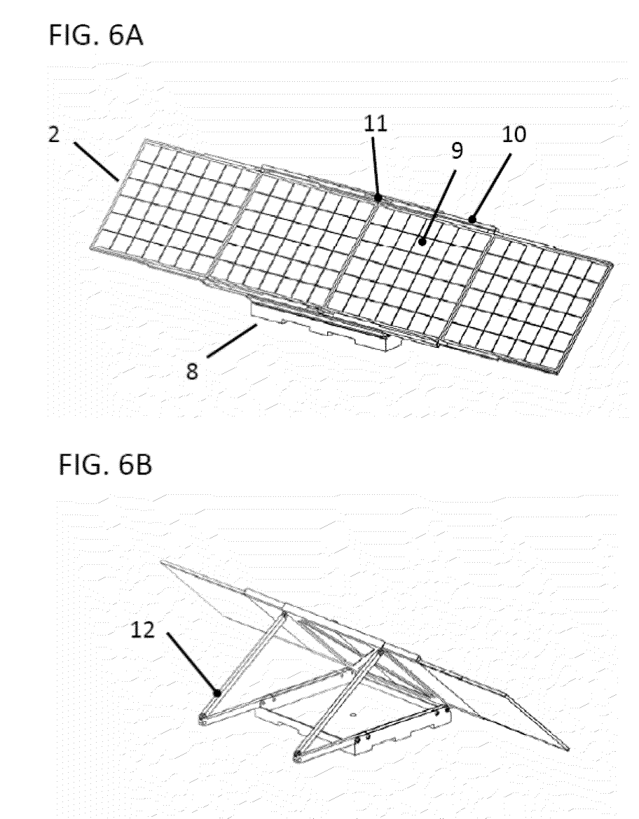

FIGS. 6A and 6B illustrate are perspective views of the front and back of an exemplary embodiment of the power subunit 6. Solar modules 9 may be attached to one more module frames 10 through any means of attachment, for example adhesive, welding, fasteners, etc. The solar modules 9 may include one or more solar conversion devices 23. The solar conversion devices 23 may be any component capable of converting radiation into another form of energy. In a preferred embodiment, the solar modules 9 are rectilinear and sized to allow for the maximum number of solar conversion devices 23 to fit on its surface and still fit into any desired exterior dimensions. In alternative embodiments, the solar modules 9 may be of any shape or size and contain any amount of solar conversion devices 23. The solar conversion devices 23 may be mounted to a substrate 24. The substrate 24 may be formed from a rigid, semi-rigid, or flexible material. For example, the substrate 24 may be a solid piece of metal or plastic, a honeycomb material made from a combination of metal, plastic, or composite materials.

A pivoting means 11 may be attached between solar modules 9, substrates 24, and/or module frames 10. The array 2 may be attached to the frame 8 and the moving frame 12. The frame 8 may attach to the tracking system 17. In a preferred embodiment, the pivoting means 11 may be formed from extruded metal and rotated around pins. In alternative embodiments, the pivoting means 11 may be made of any material and manufactured using any process known to those familiar with the state of the art. In additional alternative embodiments the pivoting means 11 may include a flexible material that allows the solar modules 9 to move between open, closed, and protected states or configurations. In a preferred embodiment, the pivoting means 11 are an integral part of the module frame 10. In an alternative embodiment, the pivoting means 11 may be an integral part of the substrate 24. In an alternative embodiment, the pivoting means 11 may be a separate component that may be attached to a solar module 9 and/or the module frame 10. In an alternative embodiment, the pivoting means 11 may be attached between the substrate 24 and the solar conversion device 23.

Solar modules 9 in the array 2 may include one or a plurality connection means to allow the solar modules to be electrically linked to one another, other components of the solar power generation device, and/or external entities. Modular interconnects may interface with the connection means and facilitate the connection of the solar modules 9. The module interconnects may be integral to pivoting means 11 or module frame 10. The module interconnect may be a discreet component that is partially or completely enclosed by one or any combination of the solar module 9, pivoting means 11, and module frame 10.

The power subunit 6 may also contain one or any combination of one or more fastening features 13, one or more locating features 14, a forklift interface 15, and a human interface 16 as previously described above. In an alternative embodiment, the power subunit 6 may also contain an energy storage system 21 an electronic control system 22.

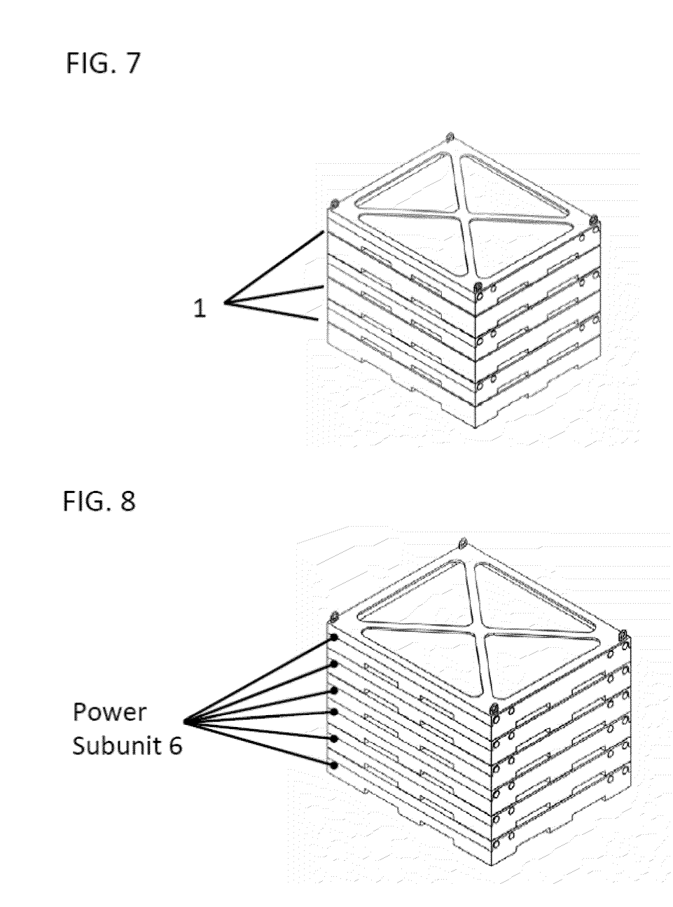

FIG. 7 illustrates an isometric view of a plurality of exemplary solar power generation devices 1 stacked on top of one another. In a preferred embodiment, the exterior length and width of the solar power generation devices 1 are sized to be the equivalent of the US Department of Defense's JMIC standard pallets. This ensures that the solar power generation devices 1 can be easily transported through military supply lines. In an alternative embodiment, the exterior length and width may be the equivalent of any specification of pallet to ensure easy transport through a variety of transportation system. In an alternative embodiment, the exterior length and width may be any values decided by the manufacturer of the solar power generation devices 1.

In a preferred embodiment, the exterior height of the solar power generation device 1 is sized such that a plurality of stacked solar generation devices 1 will be equal to or no greater than the stacking height of the US Department of Defense's JMIC standard pallet. For example, in a preferred embodiment, three solar power generation devices 1 may be stacked to equal the stacked height of the JMIC pallet. In an alternative embodiment, the exterior height could be sized to integrate with other shipping systems. In another alternative embodiment, the exterior height may equal any value decided by the manufacturer of the solar power generation devices 1.

As discussed above, in a preferred embodiment the solar power generation device 1 is divided into two sub-units; a power subunit 6 and a control subunit 7. In the preferred embodiment, both subunits 6, 7 have an associated weight and handling features that allow them to be moved by two individuals. In addition, both subunits have the features to be able to be handled by pallet moving equipment. In an alternative embodiment, the subunits can be further divided into pieces that have the weight and features to be moved by two individuals.

In the preferred embodiment of the invention, each unit and/or subunit has a fastening feature 13 located on the top of the unit. In alternative embodiments, the fastening feature may be absent.

In a preferred embodiment, the fastening feature 13 may interface with a locating feature 14 on the underside of subunits stacked on top of a given subunit. This arrangement prevents the subunits from sliding against each other. In alternative embodiments, the prevention of sliding may be handled with any geometrical interface, material that causes friction between the units, or any other fastening means. In the preferred embodiment, the subunits may be locked together using a locking mechanism (not shown). In alternative embodiments, the locking mechanism may be absent.

FIG. 8 illustrates a cross sectional view of the power subunit 6. In a preferred embodiment, the moving frame 12 and frame 8 may enclose the array 2 in the packed state or closed configuration. This may be advantageous as it protects the array 2 from damage during handling. In an alternative embodiment, the moving frame 12 and frame 8 may not entirely enclose the array 2 or may not enclose the array at all. Additional components may also be added to further protect the array 2.

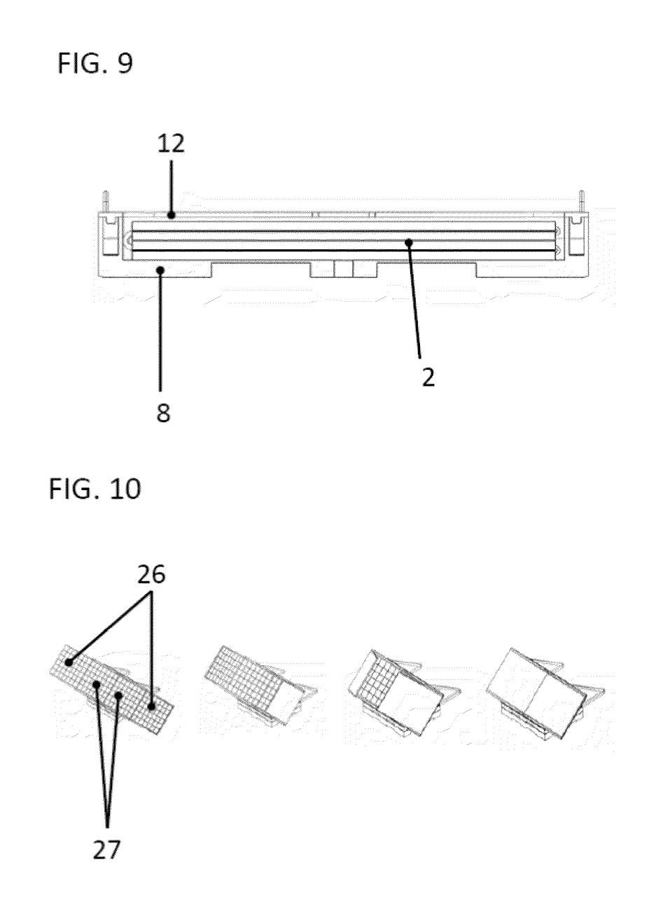

FIG. 9 illustrates a stack of power subunits 6. In a preferred embodiment, the exterior height of the power subunits 6 is sized such that a plurality of stacked solar power generation devices 1 should be equal or no greater than the stacking height of the US Department of Defense's JMIC standard pallet. For example, in the preferred embodiment, six power subunits 6 may be stacked to equal the stacked height of the JMIC pallet. In an alternative embodiment, the exterior height may be sized to integrate with other shipping systems. In an alternative embodiment, the exterior height may equal any value decided by the manufacturer of the solar power generation devices 1.

In order to be used, the preferred embodiment may be transitioned from a packed state to an open state. In the preferred embodiment, the power subunit 6 may be removed from the solar power generation device 1. At least a part of the moving frame 12 may then be removed from the frame bottom, exposing the array 2. The array 2 may then be removed from the power module 6. The moving frame 12 may then be reattached to the frame 8. The length of the members of the moving frame 8 are then adjusted to set the tilt of the array 2 to an appropriate angle for the location of the unit. Simple visual indicators (not shown) on the moving frame 12 may aid in the proper setting of the angle.

In alternative embodiments, the angle and relative position of the components could be adjusted in any way to achieve the desired position of the array 2.

In an alternative embodiment, the length of the members of the moving frame 12 may be adjusted automatically by a secondary tracking system 25 which may automatically adjust the position of the array 2 in order to orient the array more accurately towards the sun. The secondary tracking system 25 may include one or more linear actuators or any other combination of electrical and mechanical components that facilitate the motion of the array 2. The secondary tracking system 25 may be configured to transmit power and information to and from the tracking system 17 and/or the electronic control system 22.

Referring again to the previous example, the frame 8 may then be attached to the tracking system 4 in the control subunit 7. The array 2 may then be attached to the frame 8, and moved from a folded to a protected state. The array 2 may then be moved from a protected state to an open state and locked into position using a locking mechanism (not shown).

In a preferred embodiment, the array 2 may be manually moved from an open state to a protected state. FIG. 10 illustrates an exemplary method of transition from protected to open state. The outer modules 26 of the array 2 may be folded in to cover the inner modules 27. In the protected state, the module frames 10 may overlap to prevent particulate from covering the panels of the array 2. In an alternative embodiment, the module frames 10 may not overlap, or additional material may be added to create a better environmental seal. In an alternative embodiment, the transition from open to protected state may be automatic. The automatic transition may be controlled and facilitated by a panel closing system 28 which may consist of any combination of pivots, motors, gears, actuators, or any other mechanical or electronic components necessary to open and close the panels of the array 2. In an alternative embodiment, an additional component or components may be used to cover the modules when the device is in a protected state.

In an alternative embodiment, the moving frame 12 may not be removed from the frame 8. The moving frame 12 may pivot out of the way to allow the removal of the array 2. The array 2 may then be mounted to the frame 3.

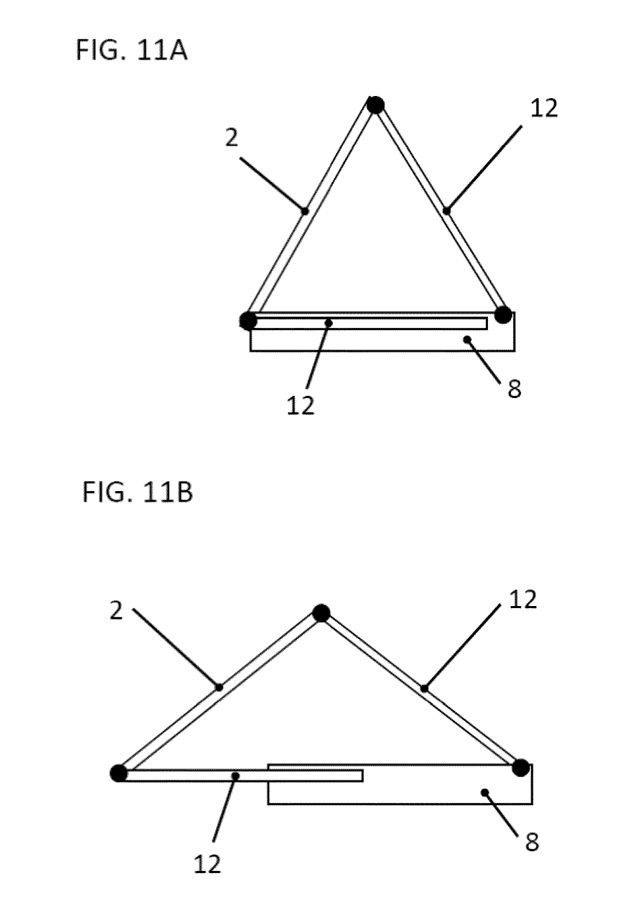

FIGS. 11A and 11B illustrate an alternative linkage for the actuation of the angle of the array 2. In this exemplary embodiment, the members of the moving frame 12 are of a fixed length and adjusted in position relative to the frame 8, thereby resulting in the pivoting of the array 2.

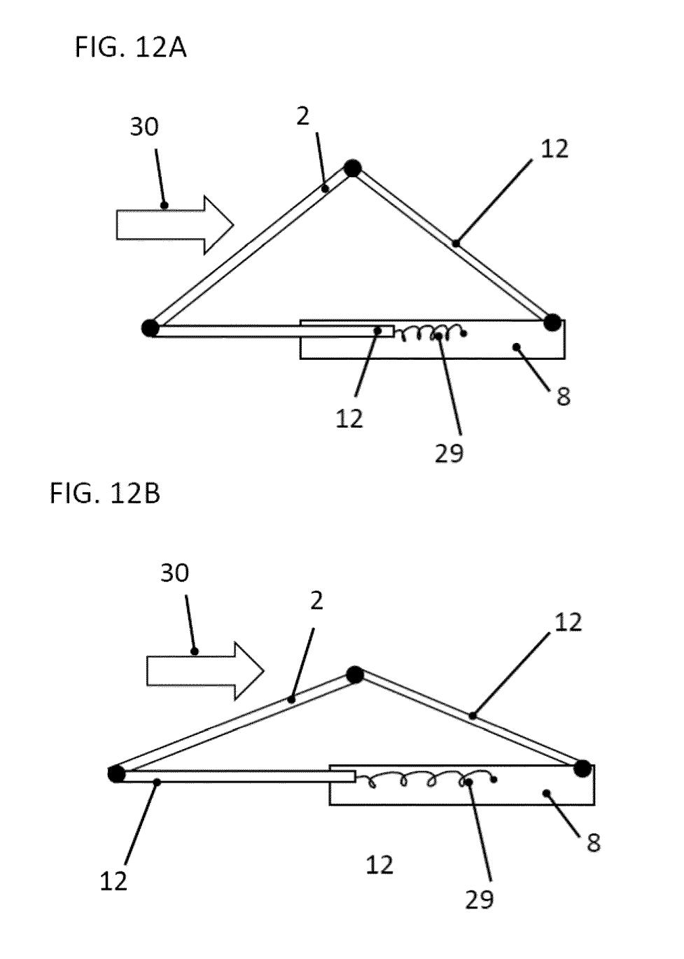

FIGS. 12A and 12B illustrates an alternative embodiment of the invention in which the moving frame 12 may be attached to the frame by a tensioning means such as a spring 29. It should be noted that spring 29 is shown by way of example only. The tensioning means may include any means configured to produce a return force when displaced such as a pneumatic or hydraulic shock. In this exemplary embodiment, a wind force 30 on the front or rear of the panel will result in the extension of the spring 29 and therefore a reduction of the angle of impact of the wind relative to the array 2. This is advantageous as it will allow the array 2 to automatically move into a position to reduce wind forces in the event of high winds resulting in reduced stress on the array as well as reduced forces acting on the device as a whole. In an alternative embodiment, a dampener may be attached in addition to the spring in order to reduce the fluctuations caused by varying forces wind forces on the array.

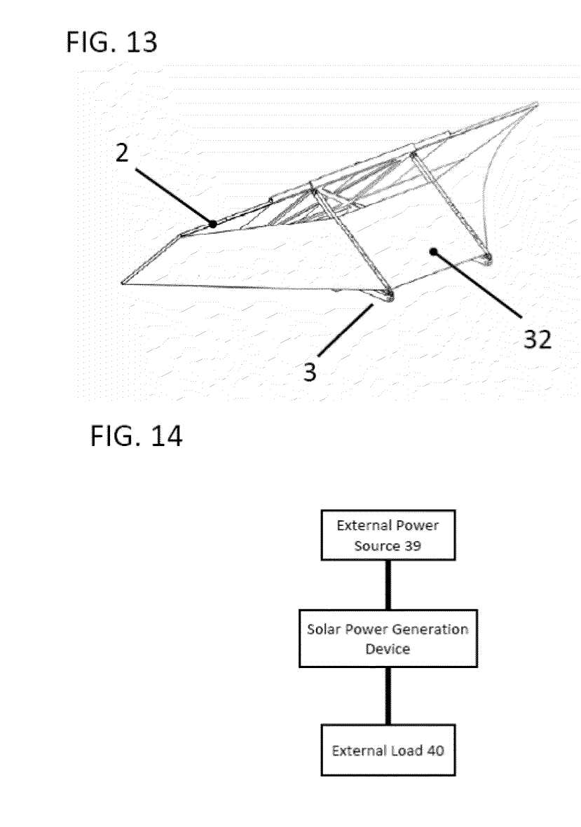

FIG. 13 illustrates an alternative embodiment of the invention in which a wind mitigation apparatus 32 may be attached to the array 2 and the frame 3 for the purpose of visual camouflage and/or the creation of an airfoil like shape to redirect and/or break airflow approaching the back of the panel. The wind mitigation apparatus 32 may consist of a perforated plastic sheet, but it should be appreciated that it may consist of any other material or form that accomplishes the same goals of visual camouflage and/or wind mitigation. The wind mitigation apparatus may cover all of the backside of the array 2 or just a portion of it. In a preferred embodiment, an opening may be created between the top of the array 2 and the wind mitigation apparatus 32 to allow for the free flow of air up the backside of the panel, allowing for unrestricted removal of heat from the backside of the panels. In a preferred embodiment, the wind mitigation apparatus 32 allows a portion of the airflow to pass through it. In alternative embodiments, the wind mitigation apparatus 32 may range from blocking all of the airflow to allowing all of it to pass through.

The tracking system 17 may allow for rotation of the power subunit 6 around a single axis or a plurality of axes. In an alternative embodiment, alternative methods of tracking are used, for example equatorial tracking, a method in which the array 2 may be rotated around a horizontal or angled axis. In a preferred embodiment, the tracking control electronics 34 (not shown) control the motion of the tracking system 17 throughout the course of operation. During the day the tracking system may continuously adjust the position of the array 2 for the purpose of orienting it towards the sun. In alternative embodiments the tracking system 4 may operate intermittently moving the array 2 a single time or a plurality of times throughout the day. The tracking control electronics may also include a direction sensing means, time tracking means, and a location sensing means. Using information from these components, the tracking control electronics may track the sun from any potential position and orientation. This is an advantageous feature in a solar power generation device 1.

In alternative embodiments, components of the tracking control electronics may be replaced or augmented by a human interface 16. The human interface 16 may be made up of components that allow for user input of time, direction, location, and any other information. For example, an embodiment of the invention may include an analog compass integrated into the case and the set up instructions may include aligning a feature of the solar power generation device 1 with a given direction. Alternatively, a standard military compass may be removably attached to the frame. The compass may then be used to orient the array 2 to the south. An input may be engaged to signal the tracking control electronics to record the position. Alternative embodiments may include a keypad and LCD screen configured to allow a user to input time, direction, and location and any other information. A preferred embodiment may include a status indicator 33 which may consist of any means of indicating the status of the device to the user.

In alternative embodiments of the invention the tracking control electronics may include one or a plurality of means to detect radiation from an external source, for example, a phototransistor. Information from this component may be used by the tracking control electronics in order to determine the position of the sun and adjust the array accordingly.

A preferred embodiment of the invention may be configured to augment another power source, for example a diesel generator. Typical power source augmenting solar battery systems are set up in situations where all variables, the solar system size, the power source size, and downstream load are known to some degree. The solar power generation device 1 may be most beneficial to such as system when it can maximize the time in which no power is drawn from the external power source. If, for example, the external power source was a diesel generator, the generator may be shut off during those times, saving fuel and reducing maintenance requirements. The present invention may be advantageous as it may detect and automatically adjust to differing deployment scenarios in order to minimize the time the external power source is required to provide power.

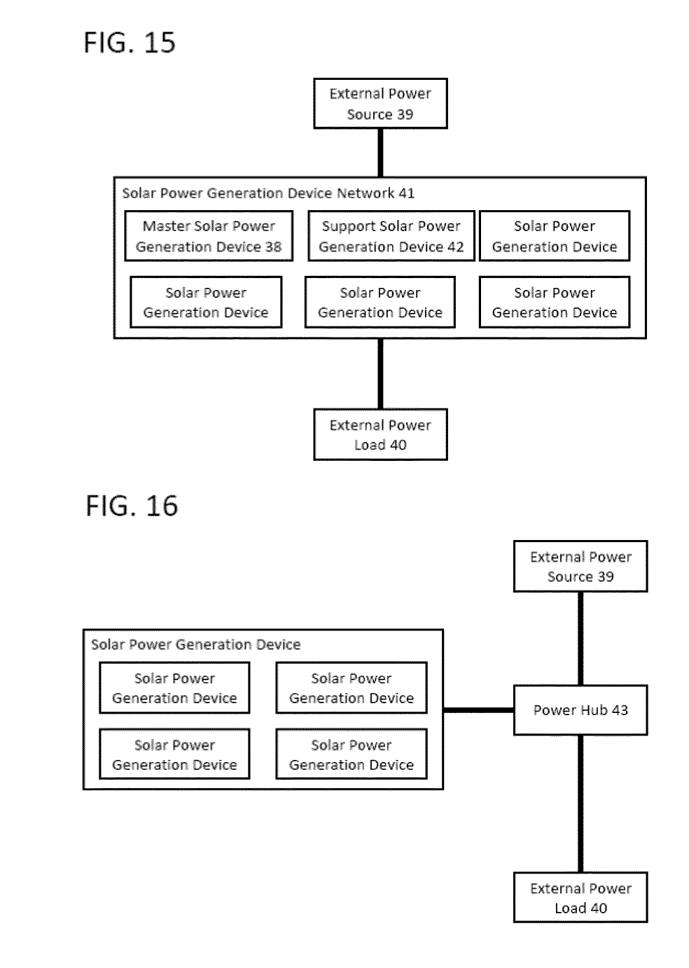

FIG. 14 illustrates a schematic view of a solar power generation device 1 connected to an external power source 39 and an external power load 40. In a preferred embodiment, one or more solar power generation devices 1 may be connected to form a solar power generation device network 41. The solar power generation devices 1 in the solar power generation device network 41 may can transmit and receive energy and information to and from each other and out of and into the network. Alternatively, the solar power generation device network 41 may function as if it were a single unit with the combined solar and battery capacity of the units comprising the solar power generation device network 41 as illustrated in FIG. 15.

In an alternative embodiment of the invention one solar generation device 1 may be a master solar generation device 38. An external power source 39 and an external power load 40 may be electrically connected to the master solar power generation device 38. One or a plurality of additional solar power generation devices may be attached to the master solar power generation device 38 and serve as a support solar power generation devices 42. In a preferred embodiment, all support solar power generation devices 42 may be connected directly to the master solar generation device 38. In an alternative embodiment, the generation devices may be connected in any configuration, for example in series, in parallel, or in any combination of the two or other methods. In additional embodiments, there may be no distinction between the master solar power generation device 38 and the support solar power generation devices 42.

In a preferred embodiment, the electronic control system 22 may direct the appropriate amount of power from the solar conversion device 23, energy storage system 21, external power source 39, and/or other solar power generation devices 1 to meet the external load. The electronic control system 22 may be able to detect the maximum power output of the external power source 39. Additionally, the electronic control system 22 may be able to detect, record, and process information relating to the energy produced by the solar conversion device 23, external power source 39, and/or other solar power generation devices 1 at any given time. Additionally, the electronic control system 22 may be able to detect, record, and process information relating to the external power load 40. Over time, the electronic control system 22 may be able to predict future loads at any given time based upon historic data indicating the characteristics of the components and energy flow within the system. The electronic control system 22 may then use these predictions to create and implement a strategy to minimize external power source usage. This may be advantageous if the external power source 39 is a combustion generator as it will minimize both the generator run time and the number of times the generator must be started and stopped.

FIG. 16 illustrates an alternative embodiment of the invention in which a power hub 43 may be used to network various solar power generation devices together. The solar power generation device network 41, external power source 39, and external load 40 may operably connect to the power hub 43 to form a larger network.

In alternative embodiments of the invention the solar power generation device 1 may be connected to zero, one, or a plurality of external power sources 39 and, likewise, to zero, one, or a plurality of external loads 40.

Alternative embodiments of the invention may include a connection means, a communications means, an external monitoring means, and/or an external control means. One or a combination of these components may allow for the transmission of energy and/or information to and from the solar power generation device 1 in order to allow a user to monitor the performance of a unit or control a unit remotely.

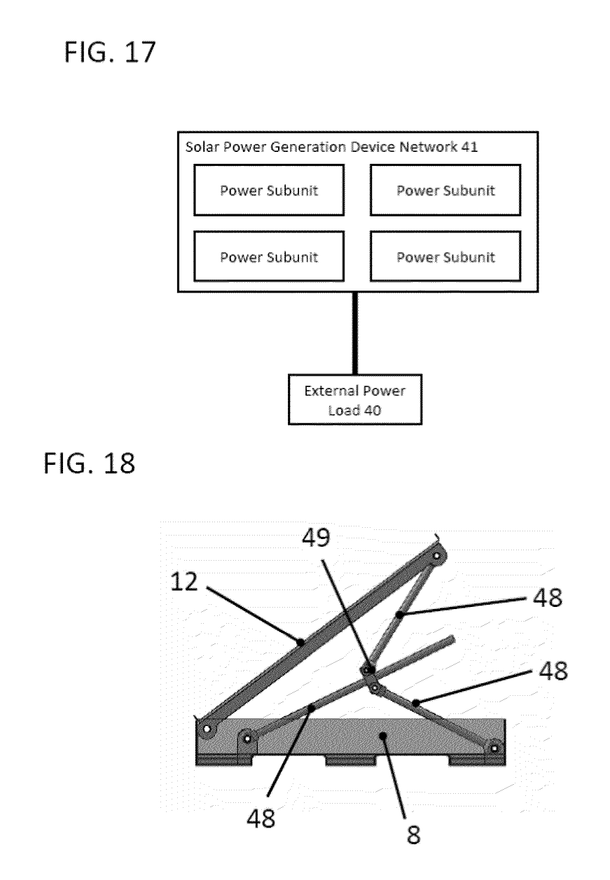

FIG. 17 illustrates an alternative embodiment of the invention in which the power subunits 6 may include an electronic control system 22, energy storage system 21, and a connection means to allow for an electrical connection between a plurality of power subunits and or an external power load 40. Power subunits may be networked together in the same fashion as described for the solar generator above.

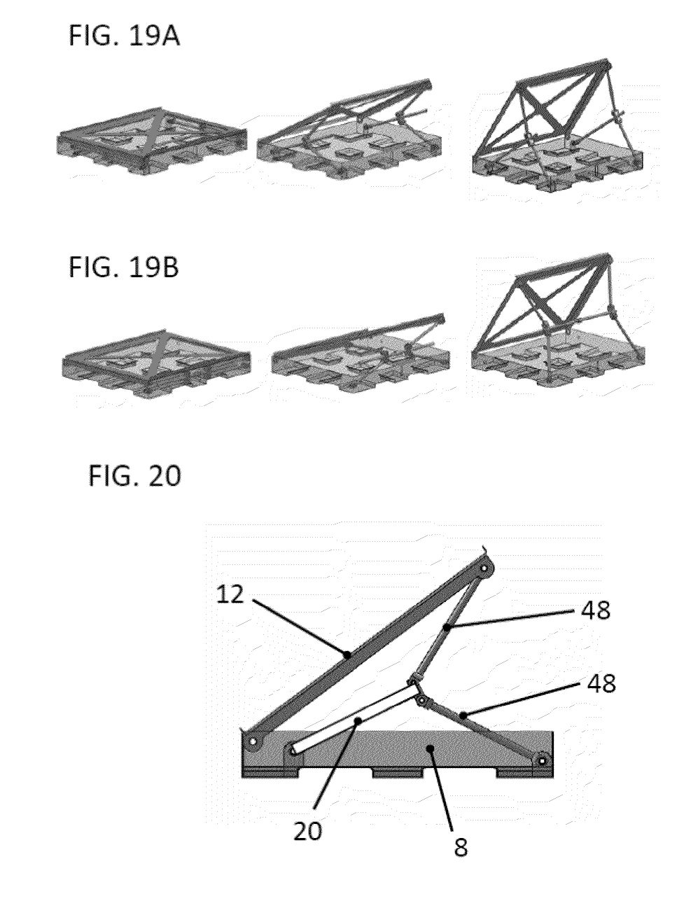

FIG. 18 illustrates an alternative embodiment of the frame 8. One or more frame links 48 may be pivotally connected to the frame 8 and the moving frame 12. The frame links 48 may then be pivotally connected to a sliding link 49. The sliding link 49 may be configured to move along a frame link in order to adjust the position of the array 2 as shown in FIGS. 19A and 19B. In an alternative embodiment, the frame 8 may include various numbers of frame links 48 and sliding links 49 that facilitate the sliding of one component against another. A restraining means 50 may be included to fix the position of the sliding link on the frame link 48.

In an alternative embodiment of the invention a spring, as defined as any component or combination of components capable of applying a return force in response to displacement, and/or a dampener, as defined as any component or combination of components that can absorb kinetic energy, may be included in the frame 8, in order to allow for controlled motion in the presence of a force on the array.

FIG. 20 illustrates an alternative embodiment of the frame 8. A frame link 48 may be replaced by an actuator 20. In an alternative embodiment, an actuator may replace any part of the frame 8, moving frame 12, or frame links 48.

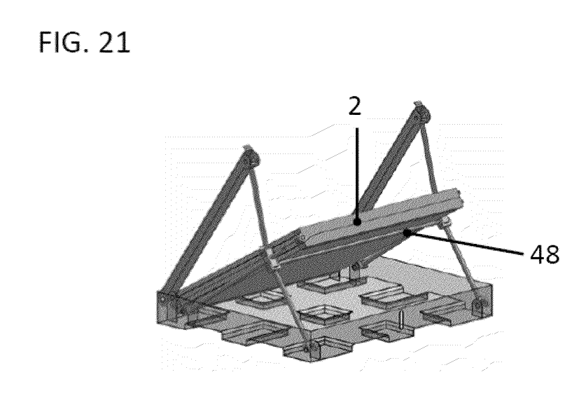

FIG. 21 illustrates alternative embodiments of frame 8 in which a frame link 48 functions to lift the array 2 into a position that facilitates removal. In an alternative embodiment, any combination of other components may be used to achieve this lifting function.

Electrical energy captured by the array may be transferred to an electrical conditioning and management system which may convert the electricity into a form that may be used by the solar power generation device. The electrical conditioning and management system may also convert the electricity into a form that is suitable for output to other active devices that require electricity for operation. This output may also be used to supplement power from another source such as a diesel generator as discussed above. The electricity for use within the solar power generation device may be stored in a short-term energy storage system, which may include a battery, a capacitor, some combination thereof, or any other suitable energy storage system or device. The electricity may also be stored in a long-term energy storage system, which may store energy that is needed to reactivate the solar power generation device after it enters the closed or inactive state. The electricity from the electrical conditioning and management system, the short-term energy storage system, and the long-term energy storage system may be used to power the tracking system or other systems associated with the solar power generation device.

The solar power generation device may further include a data acquisition system. The data acquisition system may include one or more sensors that collect data about the external environment of the solar power generation device. The sensors may also collect data about the internal operating conditions of the device, such as the amount of electricity being generated.

The electrical conditioning and management system and the data acquisition system may be connected to the energy and data transmission interface, which may include a circuit for connecting to an electrical junction on the exterior of the solar power generation device. An electrical wire or cable may be linked to the junction to transfer energy and data to and from the solar power generation device. The electrical wire or cable may be linked to other devices, or to a complimentary device. The energy and data transmission interface may transfer energy and data out of the device. Alternatively, energy and data may be transmitted to and from the device wirelessly.

In an alternative embodiment, an array cleaning system may be included. The array cleaning system may contain one or more components whose function results in the removal of particulate (e.g., sand, dust, leaves or other particulate) from the array. The array cleaning system may include components that push, pull, suck, or blow, or otherwise move the particulate from the array. The array cleaning system may also include components that create motion in the array that causes the particulate to fall off, for example, a small high frequency oscillation or a large slow shaking motion.

In an alternative embodiment, one or more of the components used in the manufacture and assembly of the solar power generation device may be finished in order to reduce reflection and refraction of radiation contacting the device and transmission of radiation from the device. For example, one or more of the components may be painted a dark color, coated with an anti-reflective film or anodized. Additionally the components may be formed from materials that reduce reflection and refraction of radiation contacting the device and transmission of radiation from the device.

It will be appreciated that several of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A solar power generation device comprising:
a power subunit comprising an array configured to collect solar radiation; and
a control subunit removably connected to the power subunit and configured to provide control and motion to the power subunit.

2. The solar power generation device of claim 1, wherein the array comprises:
a module frame;
at least one solar module operably connected to the module frame; and
a pivoting means operably connected to the at least one solar module and configured to facilitate movement of the at least one solar module from a closed configuration to an open configuration.

3. The solar power generation device of claim 1, wherein the power subunit further comprises:
a frame configured to support the array;
a moving frame operably connected to the frame and configured to move the array;
at least one fastening feature;
at least one locating feature;
at least one forklift interface; and
a human interface.

4. The solar power generation device of claim 1, wherein the control subunit comprises:
a base; and
a tracking system operably connected to the base and configured to position the array relative to a source of the solar radiation.

5. The solar power generation device of claim 4, wherein the tracking system comprises:
a rotation means configured to rotate the array; and
an actuator operably attached to the rotation means and configured to actuate movement of the rotation means.

6. The solar power generation device of claim 5, wherein the base comprises:
an energy storage system;
an electronic control system;
at least one fastening feature;
at least one locating feature;
at least one forklift feature; and
a human interface.

7. The solar power generation device of claim 1, wherein the solar power generation device is configured to be stacked in a closed configuration with other similar solar power generation devices on a pallet.
